(19) United States
(12) Patent Application Publication
(10) Pub. No.: US 2025/0218883 A1
(43) Pub. Date: Jul. 3, 2025

(54) SUBSTRATE TYPE SENSOR, WAFER TYPE SENSOR AND SUBSTRATE PROCESSING METHOD

(71) Applicant: SEMES CO., LTD., Cheonan-si (KR)

(72) Inventors: Yong Jun SEO, Hwaseong-si (KR); Sang Hyun SON, Busan (KR); Young Sik BANG, Yongin-si (KR); Ik Ho LEE, Yongin-si (KR); Sang Min HA, Hwaseong-si (KR); Kwang Sup KIM, Asan-si (KR)

(73) Assignee: SEMES CO., LTD., Cheonan-si (KR)

(21) Appl. No.: 18/980,738

(22) Filed: Dec. 13, 2024

(30) Foreign Application Priority Data
Dec. 27, 2023 (KR) 10-2023-0192575

(51) Int. Cl. H01L 23/31; H01L 21/66; H01L 23/13; H05K 1/03

(52) U.S. Cl. CPC H01L 23/3121; H01L 22/34; H01L 23/13; H01L 23/3135; H05K 1/0393

(57) ABSTRACT

Disclosed is a substrate-type sensor including: a base substrate; an electronic component positioned on a top side of the base substrate; and an elastic cover for covering the electronic component and the base substrate.

### CROSS-REFERENCE TO RELATED APPLICATIONS

This application claims priority to and the benefit of Korean Patent Application No. 10-2023-0192575 filed in the Korean Intellectual Property Office on Dec. 27, 2023, the entire contents of which are incorporated herein by reference.

### TECHNICAL FIELD

The present invention relates to a substrate type sensor, a wafer type sensor, and a substrate processing method.

### BACKGROUND ART

To manufacture semiconductor devices, a desired pattern is formed on a substrate, such as a wafer, through various processes such as photography, etching, ashing, ion implantation, and thin film deposition. Various treatment liquids and treatment gas are used in each process, and particles and process by-products are generated during the process. Cleaning processes are performed before and after each process to remove these particles and process by-products from the substrate.

A typical cleaning process includes liquid-treating the substrate with a chemical and a rinse solution. The substrate is then dried to remove any residual chemicals and rinse solution on the substrate. One example of a drying treatment is a rotary drying process in which the substrate is rotated at high speeds to remove any residual rinse solution on the substrate. However, the foregoing rotary drying method may disrupt the pattern formed on the substrate.

Recently, a supercritical drying process has been utilized in which the residual rinse solution on the substrate is replaced with an organic solvent, such as isopropyl alcohol (IPA), which has a low surface tension, by supplying the organic solvent on the substrate and the substrate is then supplied with supercritical drying gas (for example, carbon dioxide) to remove the residual organic solvent from the substrate. In the supercritical drying process, the drying gas is supplied to a process chamber with the sealed interior, and the drying gas is heated and pressurized. Both the temperature and the pressure of the drying gas rise to the critical point or above, and the drying gas undergoes a phase change to the supercritical state. In order for the drying gas to remain supercritical, the process chamber needs to be maintained at high pressure.

Meanwhile, various attempts are being made to monitor the process environment while the substrate is being processed in the process chamber. This is because when the process environment is monitored precisely, the process recipe for the substrate may be set more precisely to reflect the process environment.

Recently, wafer type sensors with the same or similar shape as the substrate have been used to monitor the process environment. The wafer type sensor is loaded into the process chamber and exposed to the same process environment in which the substrate is processed. Sensor devices attached to the wafer type sensor collect data, such as temperature and pressure. From this, an environment in which the substrate is subjected while the substrate is being processed in the process chamber is estimated.

FIG. 1 is a cross-sectional view of a typical wafer type sensor.

Referring to FIG. 1, a typical wafer-type sensor 40 includes a bottom substrate 41, a circuit board 43, a sensor element 44, and a cover substrate 45. The bottom substrate 41 may be a silicon wafer. The lower substrate 41 has a groove formed in which the circuit board 43 and the sensor device 44 may be disposed. The cover substrate 45 covers the upper portion of the groove. The grooves formed in the cover substrate 45 and the bottom substrate 41 may be combined with each other to define a cavity 42. The cover substrate 45 may be the same silicon wafer as the bottom substrate 41.

When the typical wafer-type sensor 40 is loaded into a process chamber that is maintained at high pressure, the cover substrate 45 may be damaged by the high pressure. In this case, the cavity 42 in which the sensor device 44 is disposed may not be retained. When the cavity 42 is not maintained, the sensor element 44 may be directly exposed to the process environment. In this case, the sensor element 44 may become damaged or contaminated and may not function properly.

To avoid these issues, a method of increasing the thickness of the cover substrate 45 and/or filling the cavity 42 with reinforcing material may be considered. However, this increases the overall thermal capacity of the wafer-type sensor 40, which results in differences in temperature compatibility with the actual substrate being processed (e.g., rate of response to temperature, final temperature reached, etc.).

Additionally, increasing the thickness of the cover substrate 45 may increase the difference in weight, thickness, shape, and the like from the actual substrate being processed, making it difficult to accurately monitor the process environment.

### SUMMARY OF THE INVENTION

The present invention has been made in an effort to provide a substrate-type sensor, a wafer-type sensor, and a substrate processing method that are capable of precisely monitoring a process environment.

The present invention has also been made in an effort to provide a substrate-type sensor, a wafer-type sensor, and a substrate processing method that have no or very small differences in temperature compatibility and shape with an actually processed substrate.

The present invention has also been made in an effort to provide a substrate-type sensor, a wafer-type sensor, and a substrate processing method that precisely estimate a process environment to which a substrate to be actually processed is exposed, thereby enabling precise setting of process recipes.

The object of the present invention is not limited thereto, and other objects not mentioned will be clearly understood by those of ordinary skill in the art from the following description.

An exemplary embodiment of the present invention provides a substrate-type sensor including: a base substrate; an electronic component positioned on a top side of the base substrate; and an elastic cover for covering the electronic component and the base substrate.

According to the exemplary embodiment, the substrate-type sensor may further include a circuit board positioned between the base substrate and the electronic component.

According to the exemplary embodiment, the circuit board may be a Flexible Printed Circuit Board (FPCB), which is made of a flexible material.

According to the exemplary embodiment, the elastic cover may be a flexible film made of a resin.

According to the exemplary embodiment, the elastic cover may be a film made of a material including silicone, epoxy, polyimide (PI), PTFE (Teflon), or PEEK.

According to the exemplary embodiment, the base substrate may be formed with an insertion groove into which the circuit board is inserted.

According to the exemplary embodiment, the insertion groove may be formed at a depth equal to or less than a thickness of the circuit board.

According to the exemplary embodiment, the insertion groove may be formed at a depth greater than a thickness of the circuit board.

According to the exemplary embodiment, a space between the circuit board and the elastic cover may be provided in an empty state.

According to the exemplary embodiment, a space between the circuit board and the elastic cover may be filled with a filler material.

According to the exemplary embodiment, the filler material may be an epoxy, PI resin, or silicone resin.

According to the exemplary embodiment, the insertion groove may be formed at a depth equal to a thickness of the circuit board, and the elastic cover may include: an elastic sheet placed on a top surface of the circuit board, and formed with at least one insertion hole into which the electronic component is inserted; and a cover film placed on a top surface of the elastic sheet, and covering the elastic sheet and the electronic component.

According to the exemplary embodiment, the elastic sheet may be made of a material including at least one of silicone, polyimide (PI), PTFE (Teflon), and PEEK.

Still another exemplary embodiment of the present invention provides a wafer-type sensor for monitoring a process environment in a high-pressure chamber, the wafer-type sensor including: a base substrate; a circuit board provided on the base substrate; an electronic component installed on the circuit board; and an elastic cover for covering the electronic component, and changing in thickness from a first thickness to a second thickness smaller than the first thickness during monitoring of the process environment in the high pressure chamber.

According to the exemplary embodiment, the electronic component may include a temperature sensor, a pressure sensor, an acceleration sensor, a leveling sensor, a humidity sensor, an inertial measurement sensor, a battery, a communicator, or an information processor.

According to the exemplary embodiment, the circuit board may be a Flexible Printed Circuit Board (FPCB), which is made of a flexible material.

Still another exemplary embodiment of the present invention provides a method of processing a substrate, the method including: a measurement operation of loading a substrate-type sensor into a drying chamber, in which a substrate is processed by using a supercritical fluid, to monitor a process environment in the drying chamber, the substrate-type sensor including: a base substrate; an electronic component positioned on top of the base substrate; and an elastic cover covering the electronic component and the base substrate; a recipe setting operation of, after the instrumentation operation has been performed, setting a new process recipe or modifying an existing process recipe based on data about the process environment obtained in the measurement operation; and a substrate processing operation of processing the substrate in the drying chamber based on the process recipe set in the recipe setting operation.

According to the exemplary embodiment, in the measurement operation, a supercritical fluid may be supplied into the drying chamber, wherein an overall thickness of the substrate-type sensor may be reduced.

According to the exemplary embodiment, the substrate-type sensor loaded into the drying chamber in the measurement operation and the substrate loaded into the drying chamber in the substrate processing operation may be loaded by the same transfer robot.

According to the exemplary embodiment, the substrate-type sensor and the substrate may be provided with the same thermal capacity.

According to the exemplary embodiment of the present invention, the process environment may be precisely monitored.

Further, according to the exemplary embodiment of the present invention, there may be no or very small differences in temperature compatibility and shape with an actually processed substrate.

Further, the present invention may precisely estimate the process environment to which the actual substrate being processed is exposed, enabling process recipes to be precisely set.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a cross-sectional view of a typical wafer type sensor.

FIG. 2 is a top plan view schematically illustrating a substrate processing apparatus according to an exemplary embodiment of the present invention.

FIG. 3 is a diagram schematically illustrating an exemplary embodiment of a liquid treating chamber of FIG. 2.

FIG. 4 is a diagram schematically illustrating an exemplary embodiment of a drying chamber of FIG. 2.

FIG. 5 is a cross-sectional view of a substrate-type sensor according to a first exemplary embodiment of the present invention.

FIG. 6 is a diagram illustrating monitoring a process environment of a drying chamber using the substrate-type sensor of FIG. 5.

FIG. 7 is a diagram schematically illustrating the deformation of a shape of the substrate-type sensor while monitoring the process environment of FIG. 6.

FIG. 8 is a cross-sectional view of a substrate-type sensor according to a second exemplary embodiment of the present invention.

FIG. 9 is a cross-sectional view of a substrate-type sensor according to a third exemplary embodiment of the present invention.

FIG. 10 is a diagram schematically illustrating deformation of the shape of the substrate-type sensor of FIG. 9 while monitoring a process environment in a drying chamber.

FIG. 11 is a cross-sectional view of a substrate-type sensor according to a fourth exemplary embodiment of the present invention.

FIG. 12 is a graph illustrating a result of a temperature profile according to a difference in thermal capacity of the substrate-type sensor.

FIG. 13 is a flow chart illustrating a substrate processing method according to an exemplary embodiment of the present invention.

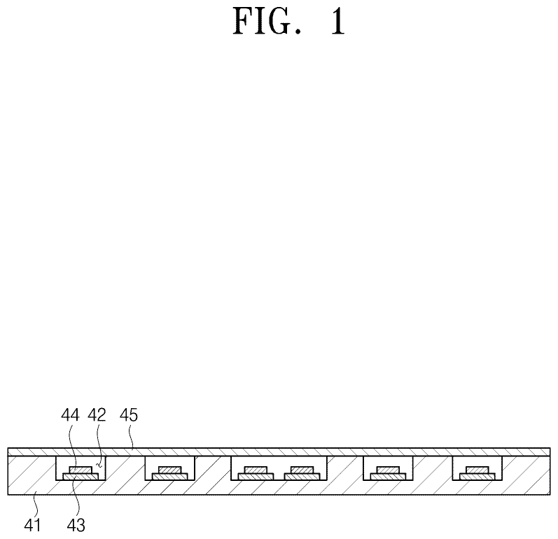

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

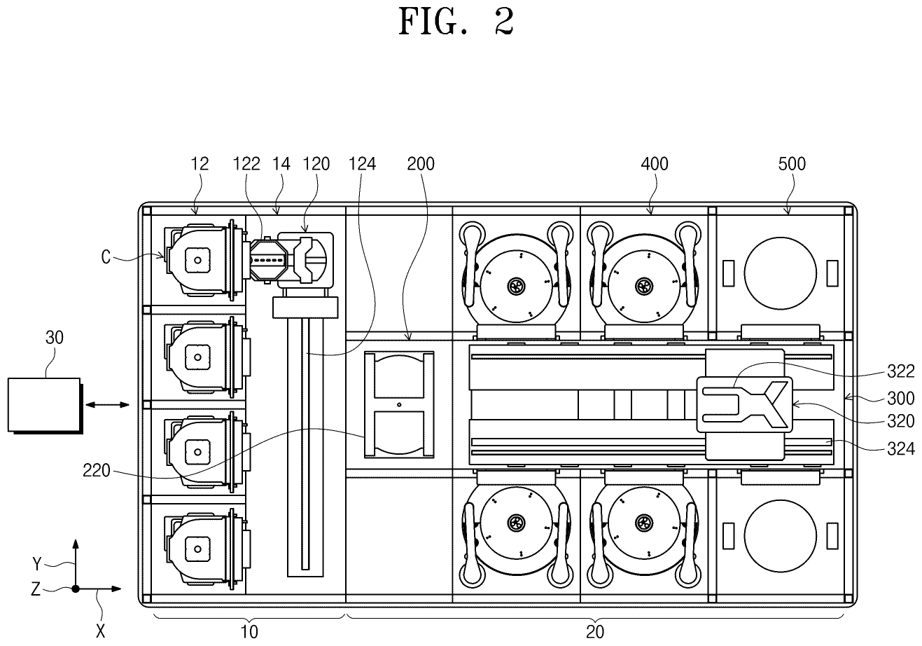

FIG. 2 is a top plan view schematically illustrating a substrate processing apparatus according to an exemplary embodiment of the present invention.

Referring to FIG. 2, a substrate processing apparatus includes an index module 10, a processing module 20, and a controller 30. When viewed from above, the index module 10 and the processing module 20 are disposed along one direction. Hereinafter, the direction in which the index module 10 and the processing module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers the substrate W from the container C in which the substrate W is accommodated to the processing module 20, and accommodates the substrate W that has been completely treated in the processing module 20 in the container C. A longitudinal direction of the index module 10 is provided in the second direction Y. The index module 10 includes a load port 12 and an index frame 14. Based on the index frame 14, the load port 12 is located at a side opposite to the processing module 20. The container C in which the substrates W are accommodated is placed in the load port 12. A plurality of load ports 12 may be provided, and the plurality of load ports 12 may be disposed along the second direction Y.

As the container C, an airtight container, such as a Front Open Unified Pod (FOUP), may be used. The container C may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate W is placed, and the hand 122 may be provided to be movable forward and backward directions, rotatable about the third direction Z and movable along the third direction Z. A plurality of hands 122 are provided to be spaced apart in the vertical direction, and the hands 122 may move forward and backward independently of each other.

The controller 30 may control the substrate processing apparatus. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treatment recipe, for executing the process in each component according to various data and treatment conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

The controller 30 may control the substrate treatment apparatus so as to perform a substrate treatment method to be described below.

The processing module 20 includes a buffer unit 200, a transfer chamber 300, a liquid treating chamber 400, and a drying chamber 500. The buffer unit 200 provides a space in which the substrate W loaded into the processing module 20 and the substrate W unloaded from the processing module 20 stay temporarily. The liquid treating chamber 400 performs a liquid treating process of treating the substrate W with a liquid by supplying a liquid onto the substrate W. The drying chamber 500 performs a drying process of removing the liquid residual on the substrate W. The transfer chamber 300 transfers the substrate W between the buffer unit 200, the liquid treating chamber 400, and the drying chamber 500.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side portion of the transfer chamber 300. The liquid treating chamber 400 and the transfer chamber 300 may be disposed along the second direction Y. The drying chamber 500 and the transfer chamber 300 may be disposed along the second direction Y. The buffer unit 200 may be located at one end of the transfer chamber 300.

According to the example, the liquid treating chambers 400 are disposed on both sides of transfer chamber 300, and the drying chambers 500 are disposed on both sides of the transfer chamber 300, and the liquid treating chambers 400 may be disposed closer to the buffer unit 200 than the drying chambers 500. At one side of the transfer chamber 300, the liquid treating chambers 400 may be provided in an arrangement of A×B (each of A and B is 1 or a natural larger than 1) in the first direction X and the third direction Z. Further, at one side of the transfer chamber 300, the drying chambers 500 may be provided in number of C×D (each of C and D is 1 or a natural number larger than 1) in the first direction 92 and the third direction 96. Unlike the above, only the liquid treating chambers 400 may be provided on one side of the transfer chamber 300, and only the drying chambers 500 may be provided on the other side of the transfer chamber 300.

The transfer chamber 300 includes a transfer robot 320. A guide rail 324 of which a longitudinal direction is provided in the first direction X is provided in the transfer chamber 300, and the transfer robot 320 may be provided to be movable on the guide rail 324. The index robot 320 includes a hand 322 on which the substrate W is placed, and the hand 322 may be provided to be movable forward and backward directions, rotatable about the third direction Z and movable along the third direction Z. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed to be spaced apart from each other along the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

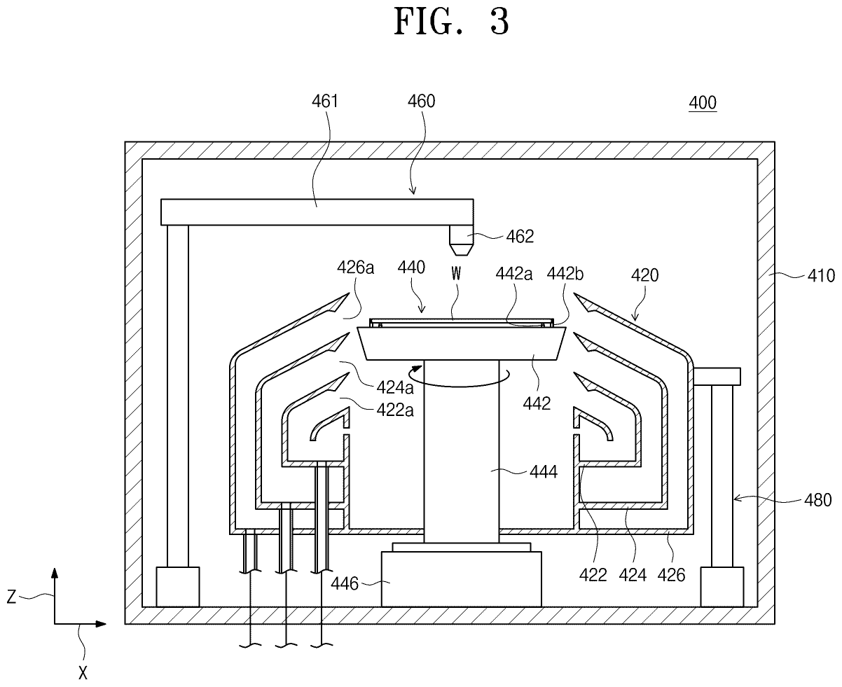

FIG. 3 is a diagram schematically illustrating an exemplary embodiment of a liquid treating chamber of FIG. 2. Referring to FIG. 3, the liquid treating chamber 400 includes a housing 410, a cup 420, a support unit 440, a liquid supply unit 460, and a lifting unit 480.

The housing 410 may have an interior space where the substrate W is processed. The housing 410 may have a generally hexahedral shape. For example, the housing 410 may have a cuboidal shape. Additionally, the housing 410 may have an opening (not illustrated) through which the substrate W is loaded or unloaded. Additionally, the housing 410 may be equipped with a door (not illustrated) that selectively opens and closes the opening.

The cup 420 may have a barrel shape with an open top. The cup 420 has a treatment space, and the substrate W may be liquid-treated within the treatment space. The support unit 440 supports the substrate W in the processing space. The liquid supply unit 460 supplies the treatment solution onto the substrate W supported on the support unit 440. The treatment solution may be provided in a plurality of types and may be supplied sequentially onto the substrate W. The lifting unit 480 adjusts a relative height between the cup 420 and the support unit 440.

According to the example, the cup 420 includes a plurality of recovery containers 422, 424, and 426. Each of the recovery containers 422, 424, and 426 has a recovery space of recovering the liquid used for the treating of the substrate. Each of the recovery containers 422, 424, and 426 is provided in a ring shape surrounding the support unit 440. As the liquid treating process proceeds, the treatment solution scattered by the rotation of the substrate W enters the recovery space through inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be located above a first inlet 422a, which introduces the liquid into the first recovery container 422, and a third inlet 426a, which introduces the liquid into the third recovery container 426, may be located above the second inlet 424a.

The support unit 440 includes a support plate 442 and a driving shaft 444. An upper surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. The drive shaft 444 is driven by a driver 446, is connected to the center of the bottom surface of the substrate W, and rotates the support plate 442 with respect to the central axis thereof.

In one example, the liquid supply unit 460 may include a nozzle 462. The nozzle 462 may deliver a treatment fluid to the substrate W. The treatment fluid may be a treatment solution. The treatment solution may be a chemical, rinse solution, or organic solvent. The chemical may be a chemical having the nature of strong acid or strong base. In addition, the rinse solution may be pure. Furthermore, the organic solvent may be isopropyl alcohol (IPA). Additionally, the liquid supply unit 460 may include a plurality of nozzles 462, each of which may supply a different type of treatment liquid. For example, one of the nozzles 462 may supply a chemical, another of the nozzles 462 may supply a rinse solution, and yet another of the nozzles 462 may supply an organic solvent. Further, the controller 30 may control the liquid supply unit 460 to supply an organic solvent from another one of the nozzles 462 to the substrate W after supplying a rinse solution from the other one of the nozzles 462. Thus, the rinse liquid supplied to the substrate W may be replaced with an organic solvent having low surface tension.

The lifting unit 480 moves the cup 420 in the up and down direction. By the up and down movement of the cup 420, a relative height between the cup 420 and the substrate W is changed. Accordingly, since the recovery containers 422, 424, and 426 for recovering the treatment solution are changed according to the type of the liquid supplied to the substrate W, the liquids may be separated and collected. Unlike the description, the cup 420 may be fixedly installed, and the lifting unit 480 may move the support unit 440 in the vertical direction.

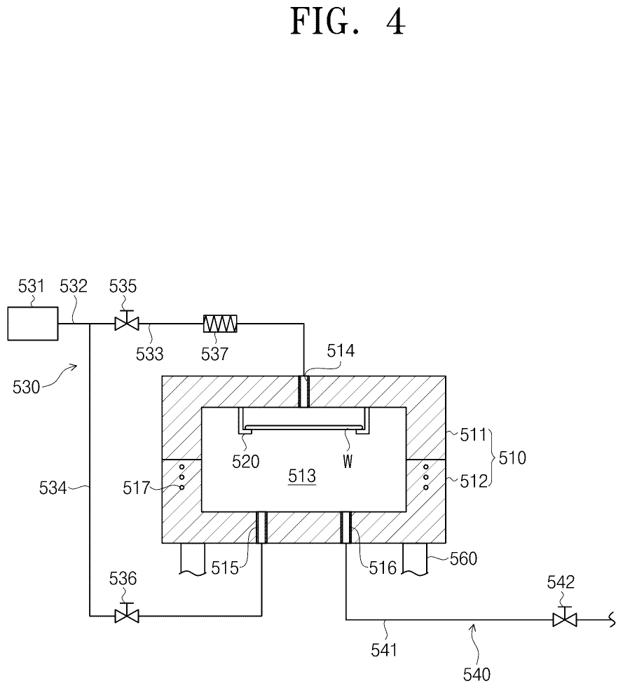

FIG. 4 is a diagram schematically illustrating an exemplary embodiment of a drying chamber of FIG. 2. Referring to FIG. 3, a drying chamber 500 according to an exemplary embodiment of the present invention may include a body 510, a support member 520, a fluid supply unit 530, a fluid exhaust unit 540, and a driver 560.

The body 510 may provide a processing space 513 where the substrate W is processed. The body 510 may include a first body 511 and a second body 512. The first body 511 and the second body 512 may be manufactured in a shape that may be combined with each other to define the processing space 513. The first body 511 may be the upper body and the second body 512 may be the lower body. The first body 511 may be the upper body and the second body 512 may be the lower body.

For example, the first body 511 may be stationary and the second body 512 may be moved in an up-and-down direction by the driver 560 that is moved by receiving power from a cylinder or motor. The second body 512 may be moved in a direction close to the first body 511 to close the processing space 513. Alternatively, the second body 512 may move in a direction away from the first body 511 to open the processing space 513.

Further, the first body 511 may be provided with a first supply port 514. The first supply port 514 may be a port formed by machining the first body 511. Alternatively, the first supply port 514 may be a port that is separately manufactured as a pipe shape and installed in a hole formed in the first body 511. The first supply port 514 may supply a drying fluid SCF to a center region of the top surface of the substrate W placed on the support member 520, which will be described later.

In addition, the second body 512 may be provided with a second supply port 515 and an exhaust port 516. The second supply port 515 and the second exhaust port 516 may be ports formed by machining the second body 512. Alternatively, the second supply port 515 and the exhaust port 516 may be ports that are separately manufactured in a pipe shape and installed in a hole formed in the second body 512. The second supply port 515 may supply the drying fluid SCF to the lower region of the processing space 513. The exhaust port 516 may exhaust the drying fluid SCF supplied to the processing space 513, and the treatment fluid IPA removed from the substrate W.

A heater 517 may be provided in the body 510. The heater 517 may be provided in the body 510 to increase the temperature of the processing space 513. The heater 517 may increase the temperature of the processing space 513 to a temperature at which the drying fluid SCF may remain supercritical. The heater 517 may be installed in both the first body 511 and the second body 512, or in any one of the first body 511 and the second body 512. FIG. 3 illustrates an example of the heater 517 being buried in the second body 512. The heater 517 may be variously modified to any known heater capable of raising the temperature of the processing space 513, such as a resistive coil.

The support member 520 may support the substrate W in the processing space 513. The support member 520 may be installed on the bottom surface of the first body 511, and may be configured to support an edge region of the substrate W. For example, one end of the support member 520 may be installed on the bottom surface of the first body 511 and the support member 520 may include a fixed portion that extends in an up and down direction, and a support portion that extends horizontally from the fixed portion. The fixed portion and the support portion may be provided as a single body, or they may be provided as separate bodies and be coupled together.

While the example described above illustrates the support member 520 being installed on the bottom surface of the first body 511, the support member 520 may also be provided in a form that is installed on the second body 512 rather than the support member 520.

The fluid supply unit 530 may supply a drying fluid (SCF to the processing space 513. The drying fluid SCF supplied by the fluid supply unit 530 to the processing space 513 may be carbon dioxide gas. The drying fluid SCF supplied by the fluid supply unit 530 to the processing space 513 may be supplied to the processing space 513 in a supercritical state, or may be supplied to the processing space 513 and changed from a gaseous state to a supercritical state.

The fluid supply unit 530 may include a fluid supply source 531, a main supply line 532, a first supply line 533, a second supply line 534, a first supply valve 535, a second supply valve 536, and a line heater 537.

The fluid supply source 531 may store and supply the drying fluid SCF. The fluid source 531 may be formed of a tank for storing the drying fluid SCF, a flow rate control device for withdrawing the drying fluid SCF from the tank at a set supply flow rate per unit time, and the like.

The main supply line 532 may be connected to the fluid supply source 531 and may be branched into a first supply line 533 and a second supply line 534. The first supply line 533 may supply the drying fluid SCF to an upper region of the processing space 513 (one example of a first region) via the first supply port 514. The second supply line 534 may supply the drying fluid SCF to a lower region of the processing space 513 (one example of a second region) via the second supply port 515.

The first supply valve 535, which may be an automatic valve (open/close valve), may be installed in the first supply line 533, and whether or not to supply the drying fluid SCF to the first supply port 514 may be selected depending on the opening or closing of the first supply valve 535. Additionally, the first supply line 533 may have the line heater 537 installed in the first supply line 533 to increase the temperature of the drying fluid SCF flowing in the first supply line 533, and the line heater 537 may increase the temperature of the drying fluid SCF to help the drying fluid SCF to be changed to the supercritical state or remain in the supercritical state. Additionally, the line heater 537 may be installed in the first supply line 533, but may be installed downstream of the first supply valve 535.

The second supply valve 536, which may be an automatic valve, is installed in the second supply line 534, and whether or not to supply drying fluid SCF to the second supply port 515 may be selected depending on the opening or closing of the second supply valve 536.

In the example described above, the first supply valve 535 and the second supply valve 536 are illustrated as being automatic valves, but without limitation, the first and second supply valves 535 and 536 may be provided as flow rate regulating valves capable of adjusting the supply flow rate of the drying fluid SCF.

The fluid exhaust unit 540 may exhaust the atmosphere of the processing space 513. The fluid exhaust unit 540 may include an exhaust line 541, and an exhaust valve 542. The exhaust line 541 may be connected to a pressure reducing device, such as a pump (not illustrated). The exhaust valve 542 may be an auto valve (open/close valve). The exhaust valve 542 is installed in the exhaust line 541 and may be installed downstream of the point where the exhaust line 541 is connected to a first circulation line 551 described later. Depending on the opening and closing of the exhaust valve 542, the atmosphere in the processing space 513 may be selectively exhausted.

The pressure in the processing space 513 may vary depending on the supply flow rate per unit time of the drying fluid SCF supplied by the fluid supply unit 530 and the exhaust flow rate per unit time of the fluid exhaust unit 540.

The following describes a substrate-type sensor that may be used in the above-described substrate processing apparatus. The substrate-type sensors described herein may be particularly suitable for use in the drying chamber 500, where a substrate W is processed with a high-pressure environment. However, without limitation, the substrate-type sensor may be equally or similarly used in the liquid treating chamber 400 described above. Furthermore, the substrate-type sensor described herein may have the same or similar shape as the actual substrate W being processed. Thus, the substrate-type sensor may also be referred to as a wafer-type sensor. Furthermore, since the substrate-type sensor described herein has the same or similar shape as the substrate W, the substrate-type sensor may be transferred by the transfer robot 320, which transfers the substrate W upon return. In other words, the substrate W and the substrate-type sensor may be transferred by the same transfer mechanism.

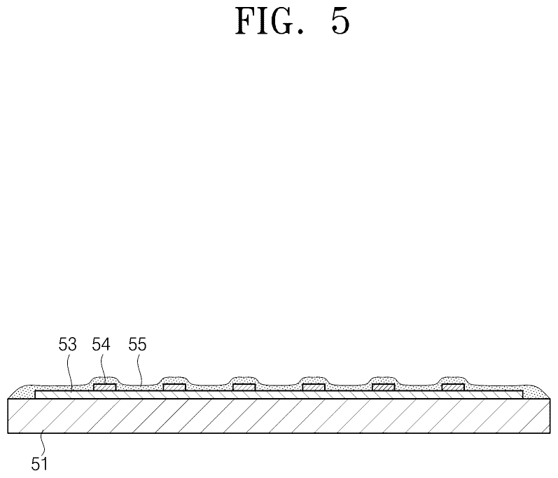

FIG. 5 is a cross-sectional view of a substrate-type sensor according to a first exemplary embodiment of the present invention.

Referring to FIG. 5, the substrate-type sensor 50 may include a base substrate 51, a circuit board 53, electronic components 54, and an elastic cover 55.

The base substrate 51 may be a lower substrate. The base substrate 51 may be made of the same or similar material as the substrate W to be treated. The base substrate 51 may be made of a material including silicon. A top surface of the base substrate 51 may have a flat shape. The circuit board 53 may be disposed on the top surface of the base substrate 51. The circuit board 53 may be a substrate on which the electronic component 54 described later may be installed. The circuit board 53 may be a printed circuit board (PCB). Alternatively, the circuit board 53 may be a flexible printed circuit board (FPCB).

The electronic components 54 described herein may be installed on the circuit board 53 and electrically connected to each other.

The electronic components 54 may be installed on the circuit board 53. There may be a plurality of electronic components 54. The plurality of electronic components 54 may be spaced apart from each other on the circuit board 53.

The electronic components 54 may be a variety of components required for the substrate-type sensor 50 to monitor the process environment. For example, the electronic components 54 may be temperature sensors, or pressure sensors. The temperature sensor may be a sensor that may measure the temperature of the environment to which the substrate-type sensor 50 is exposed. The pressure sensor may be a sensor capable of measuring the pressure of the environment to which the substrate-type sensor 50 is exposed. The temperature sensor and the pressure sensor may be any of a variety of sensors known in the art.

The electronic component 54 may also be components, such as a battery, an information processor, or a communicator. The battery may store the power required to power the substrate-type sensor 50 and may supply the stored power to the other electronic components 54 of the substrate-type sensor 50. An information processor may process and store data collected by the sensors. The information processor may include a processor and memory. The processor may process the measurement values collected by the temperature sensor or pressure sensor in the form of data over time. The processed data may be stored in the memory. The memory may be a volatile or non-volatile memory.

The communicator may be a component that enables the substrate-type sensor 50 to transmit/receive data and control signals to/from an external device, such as the controller 30. The communicator enables the information processor and the external device to transmit and receive data wirelessly. The communicator also enables the information processor and the external device to transmit and receive data in both directions.

In the examples described above, examples of the sensors that may be electronic components 54 include, but are not limited to, temperature sensors and pressure sensors. For example, the sensors may be any known sensor that are capable of monitoring the process environment to which the substrate-type sensor 50 is exposed, such as acceleration sensors, leveling sensors, humidity sensors, and inertial measurement sensors, and may be variously modified.

The elastic cover 55 may cover the circuit board 53, the electronic components 54, and the base substrate 51. It should be understood that when the elastic cover 55 covers the base substrate 51, it includes not only covering the base substrate 51 directly by contacting the base substrate 51, but also covering the base substrate 51 indirectly by contacting the circuit board 53.

The elastic cover 55 may be made of a flexible material. The elastic cover 55 may be made of a more flexible material than the base substrate 51. The elastic cover 55 may be a flexible film made of a resin. For example, the elastic cover 55 may be a PI film, or an epoxy film. Alternatively, the elastic cover 55 may be made of a material including at least one of silicone, PTFE (Teflon), and PEEK.

The elastic cover 55 is placed on the top surface of the flat base substrate 51 to cover the circuit board 53 and the electronic components 54 protruding in the upward direction. The elastic cover 55 is made of a flexible material. Therefore, the elastic cover may be relatively in close contact to the edge portions of the circuit board 53 and electronic components 54 that protrude in the upward direction.

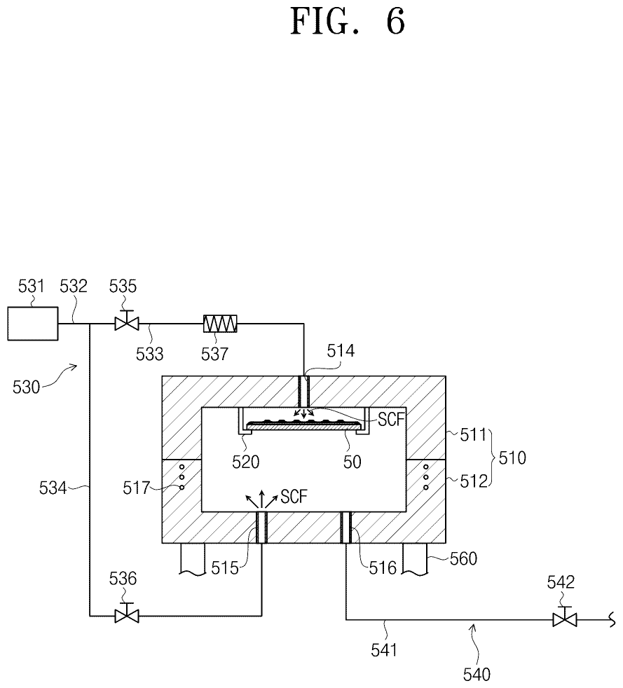

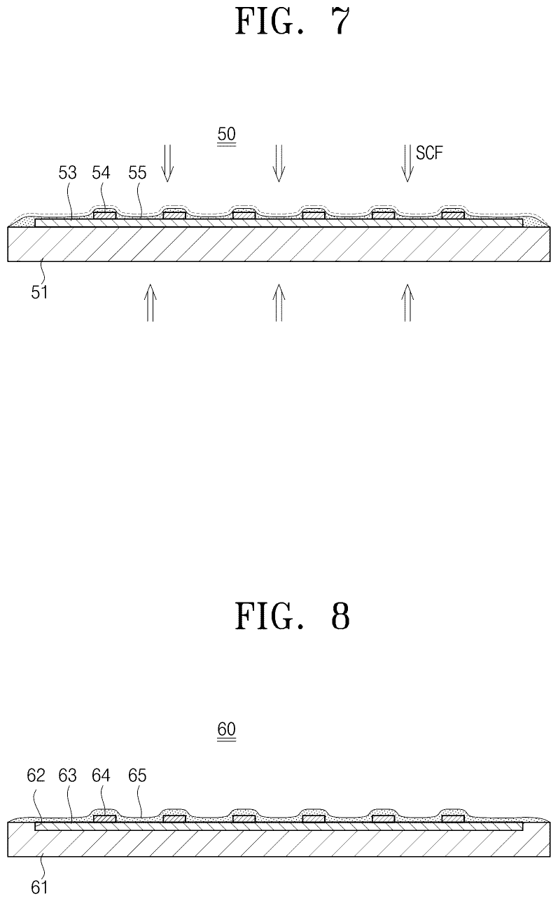

FIG. 6 is a diagram illustrating monitoring a process environment of the drying chamber using the substrate-type sensor of FIG. 5, and FIG. 7 is a diagram schematically illustrating the deformation of a shape of the substrate-type sensor while monitoring the process environment of FIG. 6.

Referring to FIGS. 6 and 7, the substrate-type sensor 50 according to the exemplary embodiment of the present invention may be brought into the drying chamber 500 to monitor the process environment in the processing space 513. For example, the substrate-type sensor 50 may be placed on the support member 520, similar to the substrate W that is to be actually processed. After the substrate-type sensor 50 is placed on the support member 520, a drying fluid SCF, which is a supercritical fluid, may be injected into the processing space 513.

In order for the drying fluid SCF to phase change to the supercritical state in the processing space 513, or for the drying fluid SCF to remain in the supercritical state, the pressure in the processing space 513 is maintained at a very high pressure (e.g., a pressure equal to or higher than a critical pressure at which the drying fluid SCF may remain in the supercritical state, e.g., a high pressure of about 100 Bar to 200 Bar).

In this case, the elastic cover 55 provided on top of the substrate-type sensor 50 is made thinner by the pressure of the processing space 513. In other words, by the high pressure of the processing space 513, the elastic cover 55 becomes thinner. Furthermore, by the high pressure of the processing space 513, the elastic cover 55 may be more tightly pressed against the electronic component 54 and the circuit board 53.

As such, as the elastic cover 55 is provided with a flexible material, it is not necessary to necessarily form a cavity for disposing the electronic components 54. Thus, a thick cover substrate may not need to be used, thereby preventing the thermal capacity of the substrate-type sensor 50 from becoming excessively large.

Furthermore, due to the high pressure in the processing space 513, the thickness of the elastic cover 55 is further reduced. For example, the resilient cover 55 before the drying fluid SCF is supplied may have a first thickness. The elastic cover 55 after the drying fluid SCF is supplied may have a second thickness that is smaller than the first thickness. When the elastic cover 55 has the second thickness, the top and bottom thickness of the substrate-type sensor 50 may be the same as the top and bottom thickness of the actual substrate W to be processed, or may have only a difference within a threshold range (e.g., a difference within 5% of the thickness of the substrate W).

Furthermore, the elastic cover 55 is in more tightly contact with the electronic component 54 and the circuit board 53. In this case, the gaps that may occur between the elastic cover 55 and the electronic components 54 and the circuit board 53 may interfere with precise measurement of the temperature sensor or pressure sensor, whereas the elastic cover 55 of the present invention is strongly in contact with the electronic components 54 and the circuit board 53 in an environment of high pressure, so that the gaps are almost eliminated. Thus, it is possible to monitor the process environment, such as temperature and pressure, more precisely.

Furthermore, as described above, the circuit board 53 may be an FPCB. In the case where the circuit board 53 is an FPCB, when the drying fluid SCF is supplied to the processing space 513, the circuit board 53 may also be compressed to further reduce its thickness. When the circuit board 53 is compressed, the degree to which the electronic components 54 protrude in the upward direction may be mitigated. When the electronic components 54 protrude excessively in the upward direction, it may affect the flow of the drying fluid SCF supplied to the electronic components 54, causing a different flow of the drying fluid SCF from the actual substrate W. When the circuit board 53 is an FPCB, the degree to which the electronic components 54 protrude may be mitigated.

Even when the circuit board 53 is an FPCB, the top and bottom thickness of the substrate-type sensor 50 after the substrate-type sensor 50 is compressed by the high pressure of the processing space 513 may be the same as the top and bottom thickness of the actual substrate W being processed, or may have only a difference within a threshold (e.g., a difference of no more than 5% of the thickness of the substrate W).

FIG. 8 is a cross-sectional view of a substrate-type sensor according to a second exemplary embodiment of the present invention.

Referring to FIG. 8, a substrate-type sensor 60 according to a second exemplary embodiment may include a base substrate 61, a circuit board 63, electronic components 64, and an elastic cover 65. The base substrate 61, the circuit board 63, the electronic components 64, and the elastic cover 65 perform the same or similar functions as the base substrate 51, the circuit board 53, the electronic components 54, and the elastic cover 55 described above, and therefore will not be described repeatedly. The following description will focus on differences from the first exemplary embodiment.

An insertion groove 62 may be formed in the base substrate 61. In the insertion groove 62, the circuit board 63 may be inserted and installed. The depth of the insertion groove 62 may be equal to the thickness of the circuit board 63. Alternatively, the depth of the insertion groove 62 may be formed to a depth less than the thickness of the circuit board 63. By providing the insertion groove 62, the previously described problem caused by the protruding of the electronic component 54 in the upward direction of the base substrate 51 may be further improved.

FIG. 9 is a cross-sectional view of a substrate-type sensor according to a third exemplary embodiment of the present invention.

Referring to FIG. 9, the substrate-type sensor 70 may include a base substrate 71, a circuit board 73, electronic components 74, and an elastic cover 75. The base substrate 71, the circuit board 73, the electronic components 74, and the elastic cover 75 perform the same or similar functions as the base substrate 51, the circuit board 53, the electronic components 54, and the elastic cover 55 described above, and therefore will not be described repeatedly. The following description will focus on differences from the first exemplary embodiment.

An insertion groove 62 may be formed in the base substrate 71. In the insertion groove 72, the circuit board 63 may be inserted and installed. The depth of the insertion groove 72 may be formed to a depth greater than the thickness of the circuit board 73. By providing the insertion groove 72, the previously described problem caused by the electronic component 54 protruding in an upward direction of the base substrate 51 may be further improved.

Furthermore, since the insertion groove 72 is provided at a relatively deep depth, a cavity CA may be formed in the space between the base substrate 71 and the elastic cover 75. The cavity CA may be filled with a filler material as desired. The filler material may be an epoxy, PI resin, or silicone resin.

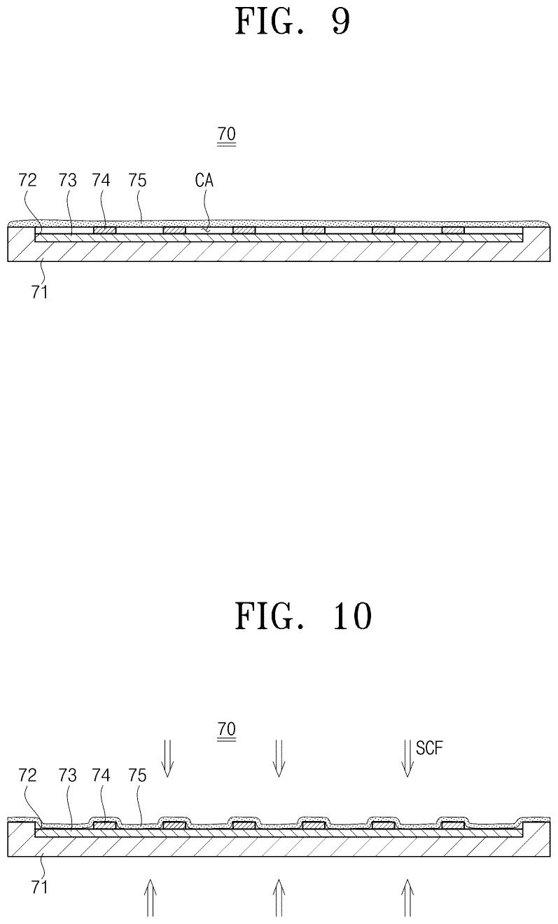

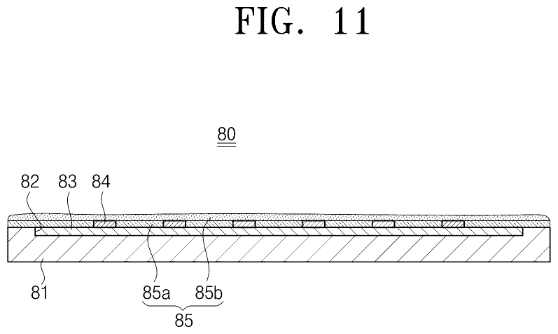

However, the cavity CA may also be provided in a blank state. Even when the cavity CA is provided empty, the high pressure of the processing space 513 may cause the elastic cover 75 to be in close contact with the electronic components 74 and the circuit board 73, as illustrated in FIG. 10. Even though some gas is present in the cavity CA, the gas may be compressed to a very small volume by the very high pressure of the processing space 513, and that volume may be negligible.

Therefore, forming the insertion groove 72 relatively deep as described above may solve the problem of protrusion of the electronic component 74 while minimizing the influence of the empty cavity CA on the measurement of pressure, temperature, and the like.

FIG. 11 is a cross-sectional view of a substrate-type sensor according to a fourth exemplary embodiment of the present invention.

The board-type sensor 80 may include a base substrate 81, a circuit board 83, electronic components 84, and an elastic cover 85. The base substrate 81, the circuit board 83, the electronic components 84, and the elastic cover 85 perform the same or similar functions as the base substrate 51, the circuit board 53, the electronic components 54, and the elastic cover 55 described above, and therefore will not be described repeatedly. The following description will focus on differences from the first exemplary embodiment.

An insertion groove 82 may be formed in the base substrate 81. In the insertion groove 82, the circuit board 63 may be inserted and installed. The depth of the insertion groove 82 may be formed at a depth equal to the thickness of the circuit board 83.

Further, the elastic cover 85 may include an elastic sheet 85a and a cover film 85b. A plurality of insertion holes may be formed in the elastic sheet 85a. The electronic components 84 may be inserted into the insertion holes. The insertion holes may be formed in a shape corresponding to the electronic components 84, and in a number corresponding to the number of electronic components 84.

The elastic sheet 85a may be positioned between the circuit board 83 and the cover film 85b. The elastic sheet 85a may be made of a silicone material in which the insertion holes are machined. This is done to have the same material as the base substrate 81, to equalize the thermal strain between the two configurations, and to have similar physical properties to the actual substrate W being processed. The cover film 85b may be made of the same or similar material as the elastic cover 55 described above.

In the examples described above, the elastic sheet 85a is illustrated as being made of the same material as the base substrate 81, but is not limited thereto. For example, the elastic sheet 85a may be made of a material including at least one of polyimide (PI), Teflon (PTFE), and PEEK.

When only the cover film 85b is provided, the uneven structure caused by the electronic component 84 may affect the flow of the drying fluid SCF supplied to the substrate W. This effect may interfere with accurate process environment monitoring by the substrate-type sensor 80. Accordingly, the elastic cover 85 may include the elastic sheet 85a to minimize the influence on the flow of the SCF caused by the uneven structure described above.

In order for the substrate-type sensors 50, 60, 70, and 80 to more accurately monitor the process environment, it is desirable that the physical properties of the substrate-type sensors 50, 60, 70, and 80 are very similar to the substrate W to be processed (standard wafer).

However, when the thickness of the cover substrate 45 is increased, or when the substrate-type sensor is provided with additional structures, in order to manufacture a substrate-type sensor that is capable of withstanding high pressure environments, the thermal capacity of the substrate-type sensor is increased by the increased thickness of the cover substrate 45 and/or the additional structures. The temperature matching between the substrate-type sensor and the substrate W is reduced by the increased thermal capacity. Therefore, it is undesirable to thicken the cover substrate 45 for a pressure-resistant design and/or to fill the cover substrate 45 with a material with a high thermal capacity, such as a reinforcing resin.

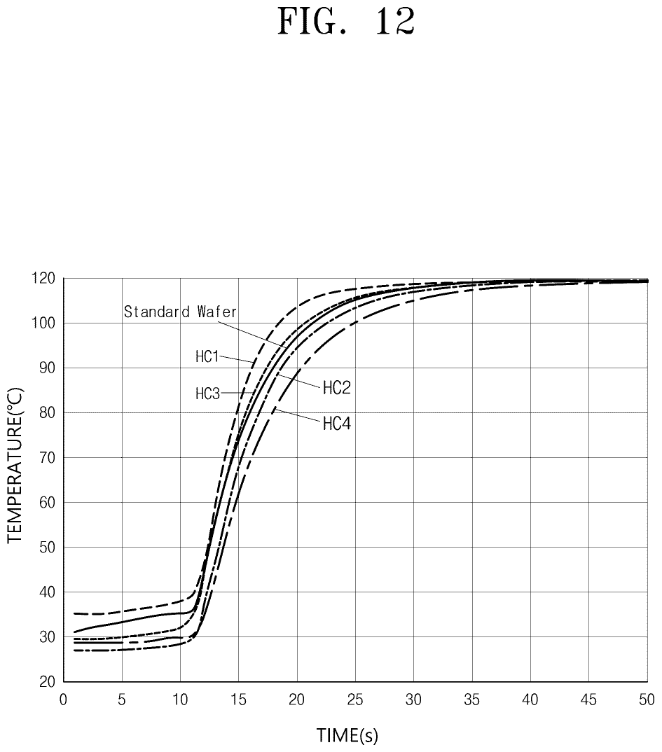

FIG. 12 is a graph illustrating a result of a temperature profile according to a difference in thermal capacity of the substrate-type sensor.

FIG. 12 shows the temperature profile results when the temperature is measured with the difference in the thermal capacity of the substrate W versus the substrate-type sensor. When the thermal capacity of the substrate-type sensor is high (e.g., HC2, HC4 case), there is a delay in the temperature rise section, or the target temperature cannot be reached within the process time. In addition, when the thermal capacity is designed to be low (e.g., HC1, HC3 case), the temperature rise rate is faster than the substrate W, making it difficult to accurately measure the process environment.

Even though the cover substrate 45 described above is designed to be very thin (e.g., about 100 micrometers), an increase in thermal capacity of 10% or more occurs. In addition, forming the cover substrate 45 thinly increases the risk of breakage due to high pressure. On the other hand, when the elastic covers 55, 65, 75, and 85 are used (e.g., PI film), only a 1% increase in thermal capacity occurs, and the risk of breakage due to high pressure may also be lowered.

Also, when necessary, to improve the thermal capacity increased by the circuit board 53, 63, 73, or 83 and the electronic component 54, 64, 74, or 84, a pattern, such as a groove, may be formed on the base substrate 51, 61, 71, or 81, or the thickness of the base substrate 51, 61, 71, or 81 may be reduced, so that the thermal capacity of the substrate-type sensor 50, 60, 70, or 80 is the same as the thermal capacity of the actual substrate W being processed.

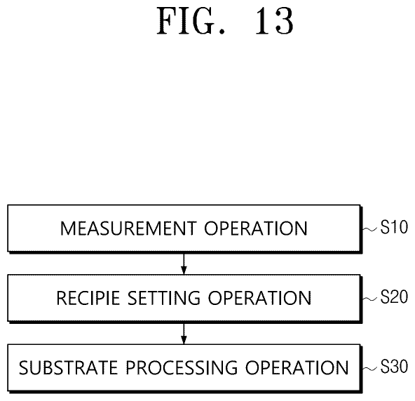

FIG. 13 is a flow chart illustrating a substrate processing method according to an exemplary embodiment of the present invention.

Referring to FIG. 13, a substrate processing method according to an exemplary embodiment of the present invention may include a measurement operation S10, a recipe setting operation S20, and a substrate processing operation S30. The measurement operation S10, the recipe setting operation S20, and the substrate processing operation S30 may be performed sequentially.

The measurement operation S10 may include loading the substrate-type sensor 50, 60, 70, or 80 into the drying chamber 500 and monitoring the process environment in the drying chamber 500. In the drying chamber 500, the substrate W may be processed through a supercritical drying fluid SCF, and the substrate-type sensors 50, 60, 70, and 80 may also be exposed to the same process environment in which the substrate W is processed.

In the measurement operation S10, the substrate-type sensors 50, 60, 70, and 80 may measure temperature, pressure, and the like. The substrate-type sensors 50, 60, 70, and 80 may have a plurality of temperature sensors and a plurality of pressure sensors, such that data may be collected about a region-specific temperature and a region-specific pressure of the substrate-type sensors 50, 60, 70, and 80. The measurement operation S10 may include collecting data on the region-specific temperature and the region-specific pressure of the substrate-type sensors 50, 60, 70, and 80 to monitor the process environment in the drying chamber 500.

When the measurement operation S10 ends, the recipe setting operation S20 may be performed. The measurement operation S10 may be used to determine the change in pressure delivered to the substrate W, the change in temperature of the substrate W, and the like, and when the profiles for the change in pressure delivered to the substrate W and the change in temperature of the substrate W are different from the targeted profiles, the existing process recipe may be modified. Modifying the process recipe may mean, for example, modifying the supply flow rate of the drying fluid SCF, the exhaust flow rate of the drying fluid SCF, the temperature of the processing space 513, the temperature of the drying fluid SCF, the timing of supplying and exhausting the drying fluid SCF, and the time taken to perform the drying process. Furthermore, based on the data obtained in the measurement operation S10, it is of course possible to modify an existing process recipe as well as to set a new process recipe.

When the process recipe is set in the recipe setting operation S20, the substrate processing operation S30 may be performed. In the substrate processing operation S30, the substrate W may be processed in the drying chamber 500 based on the process recipe set in the recipe setting operation S20.

Since the thermal capacity, thickness, and the like of the substrate-type sensor 50, 60, 70, or 80 used in the measurement operation S10 are the same as the substrate W to be processed, the process environment may be monitored more precisely. Furthermore, this enables the recipe to be set more precisely, and the substrate W may be processed effectively through the precisely set process recipe.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A substrate-type sensor comprising:
a base substrate;
an electronic component positioned on a top side of the base substrate; and
an elastic cover for covering the electronic component and the base substrate.

2. The substrate-type sensor claim 1, further comprising:
a circuit board positioned between the base substrate and the electronic component.

3. The substrate-type sensor of claim 2, wherein the circuit board is a Flexible Printed Circuit Board (FPCB), which is made of a flexible material.

4. The substrate-type sensor claim 1, wherein the elastic cover is a flexible film made of a resin.

5. The substrate-type sensor claim 1, wherein the elastic cover is a film made of a material including silicone, epoxy, polyimide (PI), PTFE (Teflon), or PEEK.

6. The substrate-type sensor of claim 2, wherein the base substrate is formed with an insertion groove into which the circuit board is inserted.

7. The substrate-type sensor of claim 6, wherein the insertion groove is formed at a depth equal to or less than a thickness of the circuit board.

8. The substrate-type sensor of claim 6, wherein the insertion groove is formed at a depth greater than a thickness of the circuit board.

9. The substrate-type sensor of claim 8, wherein a space between the circuit board and the elastic cover is provided in an empty state.

10. The substrate-type sensor of claim 8, wherein a space between the circuit board and the elastic cover is filled with a filler material.

11. The substrate-type sensor of claim 10, wherein the filler material is an epoxy, PI resin, or silicone resin.

12. The substrate-type sensor of claim 6, wherein the insertion groove is formed at a depth equal to a thickness of the circuit board, and
the elastic cover includes:
an elastic sheet placed on a top surface of the circuit board, and formed with at least one insertion hole into which the electronic component is inserted; and
a cover film placed on a top surface of the elastic sheet, and covering the elastic sheet and the electronic component.

13. The substrate-type sensor of claim 12, wherein the elastic sheet is made of a material including at least one of silicone, polyimide (PI), PTFE (Teflon), and PEEK.

14. A wafer-type sensor for monitoring a process environment in a high-pressure chamber, the wafer-type sensor comprising:
a base substrate;
a circuit board provided on the base substrate;
an electronic component installed on the circuit board; and
an elastic cover for covering the electronic component, and changing in thickness from a first thickness to a second thickness smaller than the first thickness during monitoring of the process environment in the high pressure chamber.

15. The wafer-type sensor of claim 14, wherein the electronic component includes a temperature sensor, a pressure sensor, an acceleration sensor, a leveling sensor, a humidity sensor, an inertial measurement sensor, a battery, a communicator, or an information processor.

16. The wafer-type sensor of claim 14, wherein the circuit board is a Flexible Printed Circuit Board (FPCB), which is made of a flexible material.

17.-20. (canceled)
